(19) United States
(12) Patent Application Publication
(10) Pub. No.: US 2016/0155898 A1
(43) Pub. Date: Jun. 2, 2016

(54) CURRENT BLOCK LAYER STRUCTURE OF LIGHT EMITTING DIODE

(71) Applicant: TEKCORE CO., LTD., Nantou (TW)

(72) Inventors: Hai-Wen Hsu, Nantou (TW); Ruei-Ming Yang, Nantou (TW)

(21) Appl. No.: 14/556,803

(22) Filed: Dec. 1, 2014

(51) Int. Cl. H01L 33/14; H01L 33/38; H01L 33/10; H01L 33/40; H01L 33/42

(52) U.S. Cl. CPC H01L 33/145; H01L 33/405; H01L 33/42; H01L 33/10; H01L 33/38

(57) ABSTRACT

A current block layer structure applied to a light emitting diode is provided. The LED includes a reflecting layer, an N-type electrode, an N-type semiconductor layer, a light emitting layer, a P-type semiconductor layer, a transparent conductive layer and a P-type electrode. A current block reflecting layer is disposed the transparent conductive layer at a region corresponding to the P-type electrode and an end close to the light emitting layer. The current block reflecting layer includes a Bragg reflector (DBR) structure, which allows the current block reflecting layer to reflect an excited light from the light emitting layer. Thus, the excited light emitted towards the P-type electrode is provided with a higher reflection rate and is again reflected by the reflecting layer. The excited light takes exit via regions without the N-type electrode and the P-type electrode after several reflections, thereby enhancing light extraction efficiency of the LED.

### FIELD OF THE INVENTION

The present invention relates to a light emitting diode (LED), and particularly to an LED for enhancing light emitting efficiency.

### BACKGROUND OF THE INVENTION

A light emitting diode (LED) is principally formed by multiple epitaxial layers of a light emitting semiconductor material. For example, a blue-light LED is mainly consisted of gallium nitride-based (GaN-based) epitaxial thin films that are stacked into a light emitting body in a sandwich structure. According to structures of LEDs, LEDs are categorized into horizontal, vertical and flip-chip LEDs.

Referring to FIG. 1, a conventional horizontal LED 1 includes a reflecting layer 2, an N-type semiconductor layer 3, an N-type electrode 4, a light emitting layer 5, a P-type semiconductor layer 6, a current block layer 7, a transparent conductive layer 8, and a P-type electrode 9. The N-type electrode 4 and the P-type electrode 9 are for inputting a voltage difference 10, so as to drive the sandwich structure of the N-type semiconductor layer 3, the light emitting layer 5 and the P-type semiconductor layer 6 to generate an excited light 11. The reflecting layer 2 reflects the excited light 11 such that the excited light 11 exits via a same side in a concentrated manner.

The current block layer 7 blocks a current from passing through, whereas the transparent conductive layer 8 is a transparent material that allows a current to pass through. Thus, the current block layer 7 and the transparent conductive layer 8 may be disposed between the P-type electrode 9 and the P-type semiconductor layer 6. When a current is induced via the P-type electrode 9, the current block layer 7 blocks the current from passing through, and so the current is forced to detour along the current block layer 7 to be diffused at the transparent conductive layer 8, thereby enhancing the light emitting uniformity and brightness of the light emitting layer 5.

The above structure indeed is capable of enhancing the light emitting uniformity and brightness of the light emitting layer 5. Further, when the excited light 11 emits towards the N-type electrode 4 or the P-type electrode 9, the excited light 11 is reflected. The excited light 11 is then reflected via the reflecting layer 2 to exit at a region without the N-type electrode 4 or the P-type electrode 9. However, as the N-type electrode 4 or the P-type electrode 9 is a non-transparent and light absorbent material, the excited light 11 emitted towards the N-type electrode 4 or the P-type electrode 9 is partially absorbed by the N-type electrode 4 or the P-type electrode 9, leading a significant amount of light loss.

### SUMMARY OF THE INVENTION

The primary object of the present invention is to provide one end of the P-type electrode close to the light emitting layer with a higher reflection rate, so as to allow an excited light emitted towards the P-type electrode to be reflected by a higher reflection rate, thereby increasing an effective amount of light extraction of the excited light from the light emitting layer and further enhancing the light emitting efficiency of the light emitting diode (LED).

The present invention provides a current block layer structure applied to an LED. The LED includes a reflecting layer, an N-type electrode, an N-type semiconductor layer, a light emitting layer, a P-type semiconductor layer, a transparent conductive layer and a P-type electrode. The N-type semiconductor layer is located on the reflecting layer, and includes divided areas respectively connected to the N-type electrode and the light emitting layer. The P-type semiconductor layer is located on the light emitting layer. The transparent layer is located on the P-type semiconductor layer. The P-type semiconductor layer is connected to the transparent layer. The present invention is characterized that, a current block reflecting layer is disposed at a region of the transparent layer corresponding to the P-type electrode and at an end close the light emitting layer. The current block reflecting layer includes a Bragg reflector (DBR) structure.

Accordingly, the current block reflecting layer reflects the excited light from the emitting layer to provide an excited light emitted towards the P-type electrode to with a higher reflection rate. After having been reflected by the current block reflecting layer, the excited light is further reflected by the reflecting layer for a number of times, and exits via regions without the N-type electrode and the P-type electrode. Thus, the amount of light absorbed by metal materials of the N-type electrode and the P-type electrode can be reduced, thereby increasing the light extraction efficiency of the LED and satisfying the need for enhanced brightness.

### BRIEF DESCRIPTION OF THE DRAWINGS

FIG. 1 is a structural diagram of a conventional light emitting diode (LED).

FIG. 2A is a top view of a structure of an LED of the present invention.

FIG. 2B is a sectional view of a structure of the present invention along 2B-2B in FIG. 2A.

FIG. 2C is a sectional view of a structure of the present invention along 2C-2C in FIG. 2A.

FIG. 3 is a first diagram of a reflection path of an excited light of the present invention.

FIG. 4 is a second diagram of a reflection path of an excited light of the present invention.

FIG. 5A to FIG. 5B are diagrams of simulation data of an excited entering a P-type electrode of the present invention.

FIG. 6A to FIG. 6C are diagrams of simulation data of an excited entering an N-type electrode of the present invention.

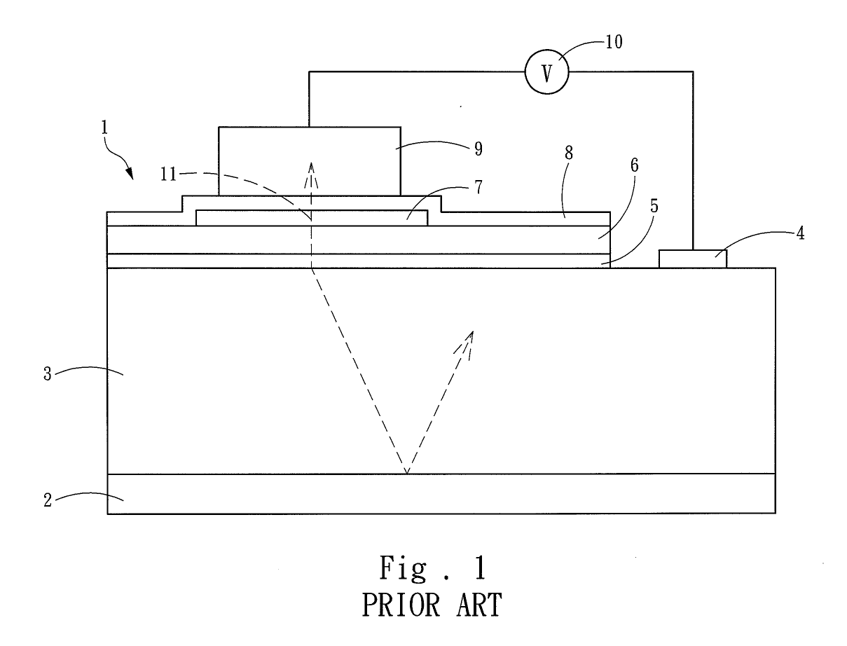

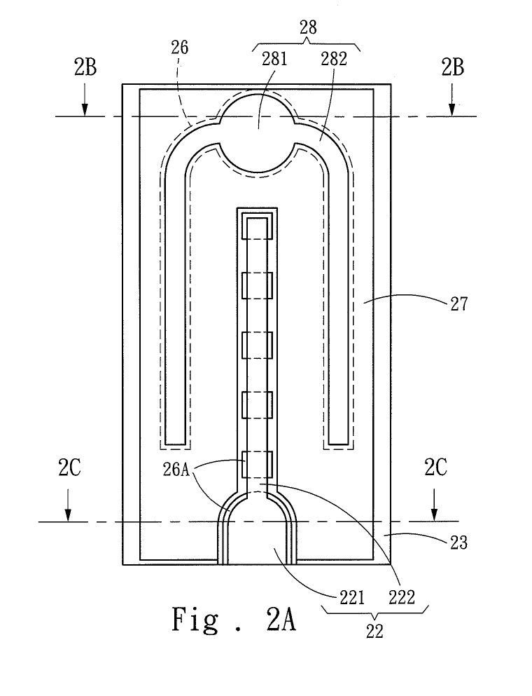

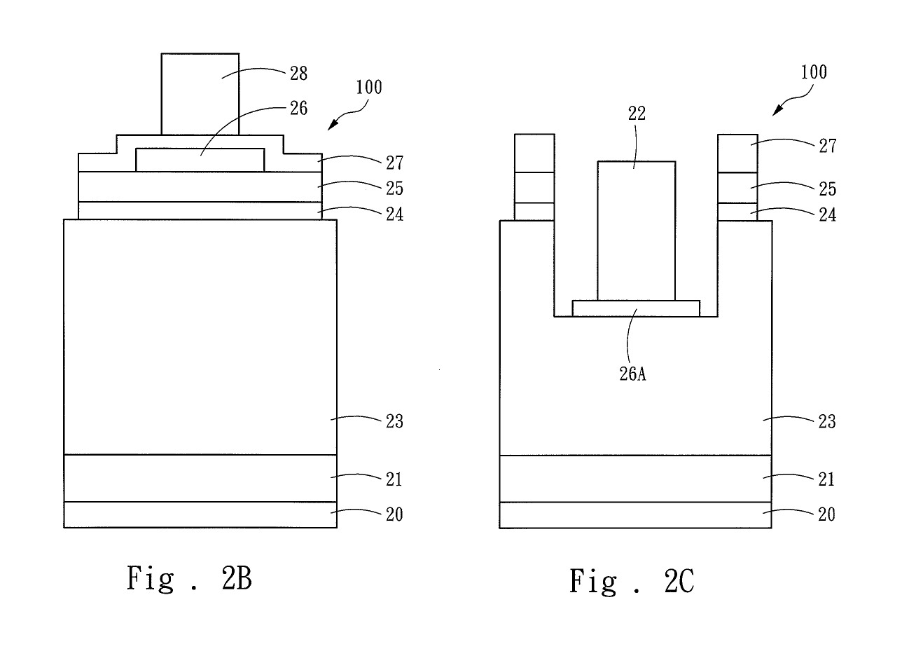

### DETAILED DESCRIPTION OF THE PREFERRED EMBODIMENTS

The foregoing, as well as additional objects, features and advantages of the invention will be more readily apparent from the following detailed description, which proceeds with reference to the accompanying drawings.

A transparent conductive layer structure of a light emitting diode (LED) is applied to an LED 100. The LED 100 includes a reflecting layer 21, an N-type electrode 22, an N-type semiconductor layer 23, a light emitting layer 24, a P-type semiconductor layer 25, a current block layer 26, a transparent conductive layer 27 and a P-type electrode 28, which are all stacked on a substrate 20. The reflecting layer 21 is located on the substrate 20. The N-type semiconductor layer 23 is located on the reflecting layer 21, and includes divided areas respectively connected to the

N-type electrode 22 and the light emitting layer 24. The P-type semiconductor layer 25 is located on the light emitting layer 24. The transparent conductive layer 27 is located on the P-type semiconductor layer 25. The P-type electrode 28 is located on the transparent conductive layer 27.

A feature of the present invention is that, at the transparent conductive layer 2, at a region corresponding to the P-type electrode 28 and at one end close to the light emitting layer 24, a current block reflecting layer 26 is disposed. At one side of the N-type electrode 22 close to the reflecting layer 21, another current block reflecting layer 26A may also be disposed. The current block reflecting layer 26 includes a DBR structure. Further, the current block reflecting layer 26 has a pattern that corresponds to the P-type electrode 28 and has an overall covering area that exceeds the P-type electrode 22. Similarly, the current block reflecting layer 26A also has a pattern that corresponds to the N-type electrode 22 and is in a discontinuous form, hence allowing the N-type electrode 22 to be connected to the N-type semiconductor layer 23.

Further, the P-type electrode 28 may be divided into a P-type contact 281 and a P-type extension electrode 282 that are connected to each other. Similarly, the N-type electrode 22 may be divided into an N-type contact 221 and an N-type extension electrode 222 that are connected to each other. Further, at the transparent conductive layer 27, at regions corresponding to the P-type contact 281 and the P-type extension electrode 282 and at an end close to the light emitting layer 24, the current block reflecting layer 26 is disposed. Further, at ends of the N-type contact 221 and the N-type extension electrode 222 close to the reflecting layer 21, the current block reflecting layer 26A is disposed. Further, the current block reflecting layer 26A at the region corresponding to the N-type extension electrode 222 is in a discontinuous form.

In practice, the P-type contact 281 is generally a circular shape, and is adapted to connect to an external voltage; the P-type extension electrode 282 is generally a long strip, and is adapted to help current distribution. Further, the N-type contact 221 is generally a circular shape, and is adapted to connect to an external voltage; the N-type extension electrode 22 is generally a long strip, and is adapted to help current distribution.

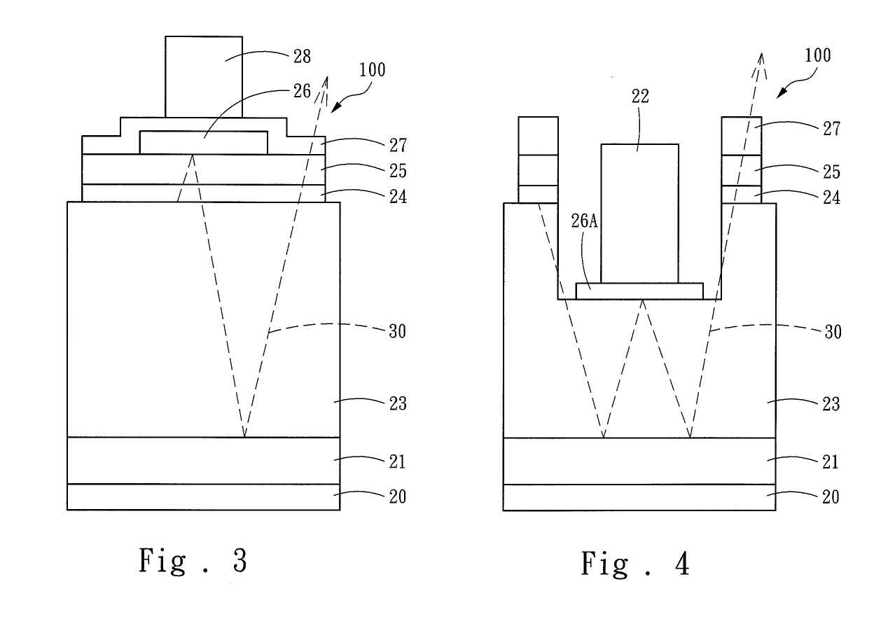

Referring to FIG. 3 and FIG. 4, both of the current block reflecting layer 20A disposed at the N-type electrode 22 and the current block reflecting layer 26 disposed at the P-type electrode 26 reflect an excited light 30 from the light emitting layer 24. The current block reflecting layers 26 and 26A are formed by alternately stacking at least two oxides with different refraction rates. For example, the materials of the current block reflecting layers 26 and 26A may be selected from silicon dioxide (SiO2) and titanium dioxide (TiO2). Further, thicknesses of the materials of the current block reflecting layers 26 and 26A are preferably between 1 Å and 20000 Å. When the excited light 30 emits towards the P-type electrode 28 or the N-type electrode 22, the excited light 30 is reflected by the current block reflecting layer 26 or 26A to yield a higher reflection rate. After having been reflected by the current block reflecting layers 26 and 26A, the excited light 30 is then again reflected by the reflecting layer 21. After multiple rounds of reflection, the excited light 30 exits via regions without the N-type electrode 22 and the P-type electrode 28.

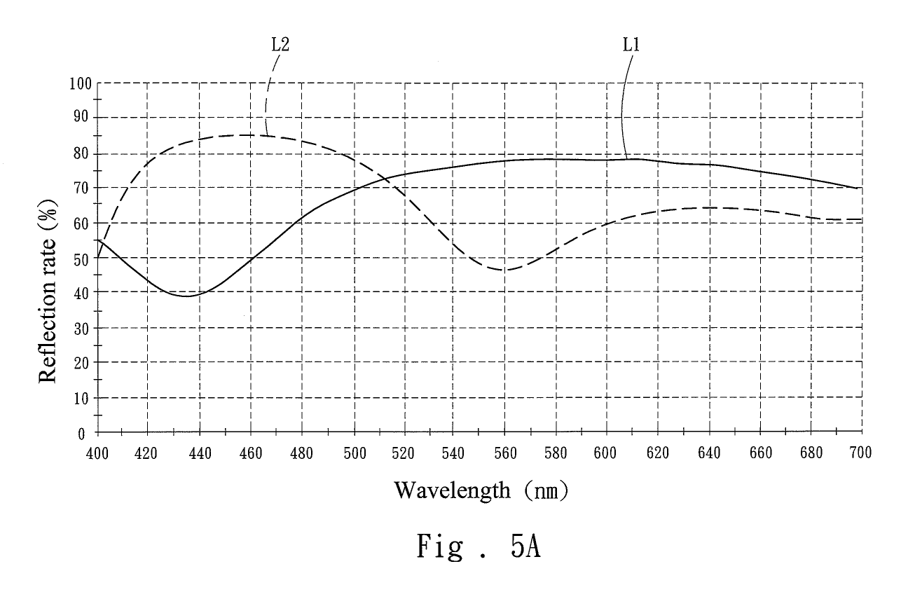

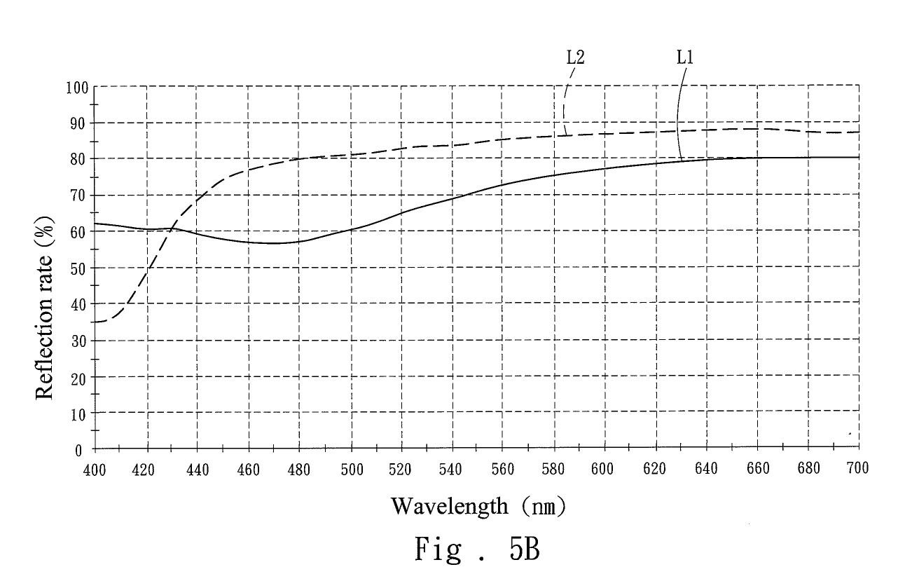

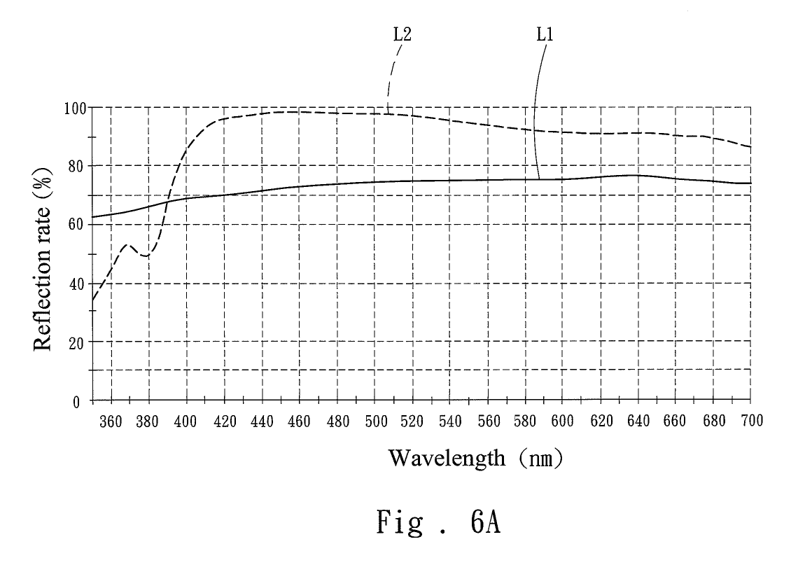

FIG. 5A and FIG. 5B show diagrams of simulation data of the present invention when the excited light 30 enters the P-type electrode 28 at incident angles of 0 degree and 30 degrees. The data is divided into two sets that respectively represent data with and without the current block reflecting layer 26. When the current block reflecting layer 26 is not provided, a common current block layer (e.g., silicon dioxide) is provided instead, and the corresponding data is indicated by a solid line L1. Data involving the current block reflecting layer 26 is represented by a dotted line L2.

As shown, at a 0-degree incident angle, for a waveband of 400 nm to 520 nm, it is observed that the reflection rate without the current block reflecting layer 26 (the solid line L1) is only about 45% to 80%, whereas the reflection rate with the current block reflecting layer 26 (the dotted line L2) rises to about 65% to 90%. At a 30-degree incident angle, for a waveband of 440 nm to 700 nm, the reflection rate without the current block reflecting layer 26 (the solid line L1) is only about 60% to 80%, whereas the reflection rate with the current block reflecting layer 26 (the dotted line L2) rises to about 65% to 90%.

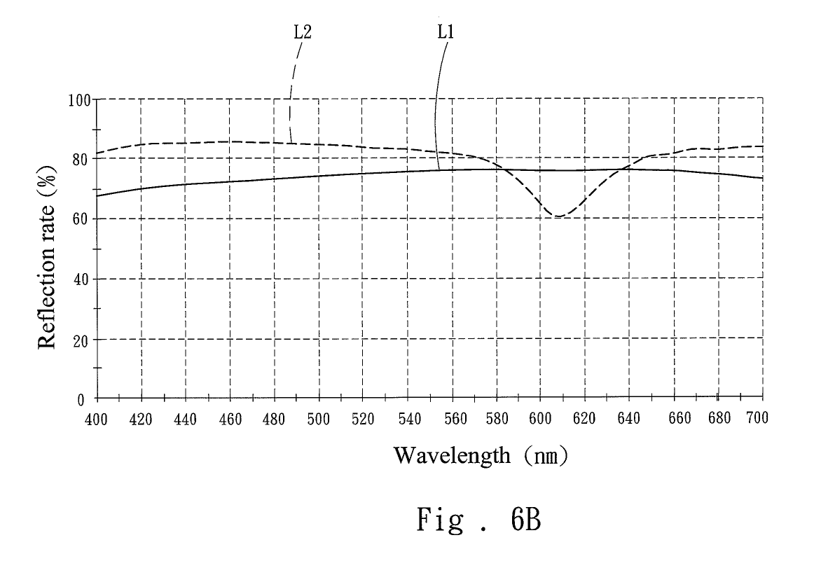

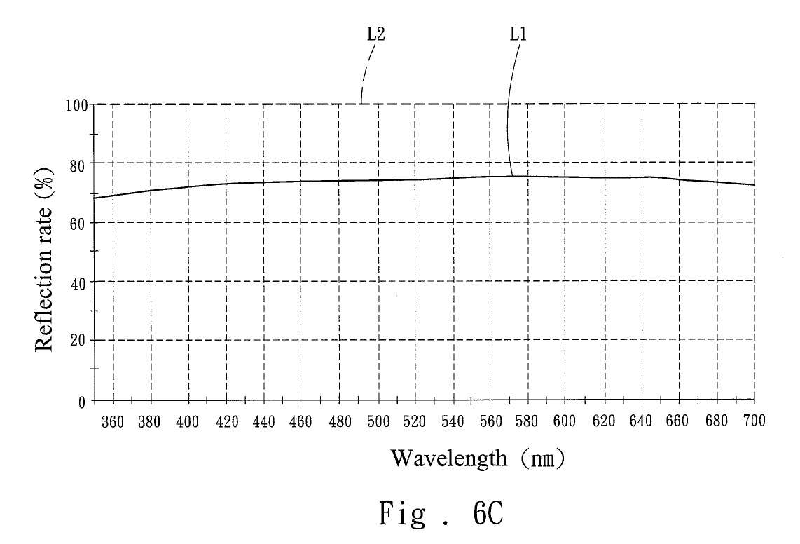

FIG. 6A, FIG. 6B and FIG. 6C are diagrams of simulation data of the present invention. The diagrams respectively show data of reflection rates of the excited light 30 entering the N-type electrode 22 at incident angles of 0 degree, 30 degrees and 60 degrees. The data is divided into two sets that respective represent data with and without the current block reflecting layer 26A. Data not involving the current block reflecting layer 26A is represented by a solid line L1, and data involving the current block reflecting layer 26A is represented by a dotted line L2.

As shown, at a 0-degree incident angle, for a waveband of 400 nm to 700 nm, the reflection rate without the current block reflecting layer 26A (the solid line L1) is only about 70% to 80%, whereas the reflection rate with the current block reflecting layer 26A (the dotted line L2) rises to about 85% to 100%. At a 30-degree incident angle, for a waveband of 400 nm to 580 nm, the reflection rate without the current block reflecting layer 26A (the solid line L1) is only about 68% to 76%, whereas the reflection rate with the current block reflecting layer 26A (the dotted line L2) rises to about 75% to 85%. At a 60-degree incident angle, for a waveband of 400 nm to 700 nm, the reflection rate without the current block reflecting layer 26A (the solid line L1) is only about 68% to 76%, whereas the reflection rate with the current block reflecting layer 26A (the dotted line L2) rises to achieve about 100% (total reflection).

It is apparent from the above data that, by providing the current block reflecting layers 26 and 26A, the reflection rate of the excited light 30 is significantly increased. That is to say, the excited light 30 entering the P-type electrode 28 and the N-type electrode 22 may be effectively reflected. Further, the excited light 30 takes exit after having been reflected for a number of times, in a way that not only the reflection rate but also the light extraction efficiency is increased, thereby by satisfying the need for enhanced brightness.

In conclusion, through providing the current block reflecting layer of the present invention, a reflection rate of an excited light emitted towards the N-type electrode and the P-type electrode is increased. The excited light then takes exit at regions without the N-type electrode and the P-type electrode after having been reflected for a number of times. Thus, the amount of light absorbed by metal materials of the N-type electrode and the P-type electrode can be reduced to increase the light extraction efficiency of the LED, thereby satisfying the need for enhanced brightness.

What is claimed is:

1. A current block layer structure of a light emitting diode (LED), applied to an LED, the LED comprising a reflecting layer, an N-type electrode, an N-type semiconductor layer, a light emitting layer, a P-type semiconductor layer, a transparent conductive layer and a P-type electrode; the N-type semiconductor layer located on the reflecting layer, the N-type semiconductor layer comprising divided areas respectively connected to the N-type electrode and the light emitting layer, the P-type semiconductor layer located on the light emitting layer, the transparent conductive layer located on the P-type semiconductor layer, the P-type electrode connected to the transparent conductive layer; the current block layer structure being characterized that:
at the transparent conductive layer, at a region corresponding to the P-type electrode and at an end close to the light emitting layer, a current block reflecting layer is disposed; the current block reflecting layer comprises a Bragg reflector (DBR) structure.

2. The current block layer structure of an LED of claim 1, wherein the current block reflecting layer has a pattern that corresponds to the P-type electrode and an overall covering area that exceeds the P-type electrode.

3. The current block layer structure of an LED of claim 1, wherein the P-type electrode comprises divided areas of a P-type contact and a P-type extension electrode that are connected to each other; at the transparent conductive layer, at regions corresponding to the P-type contact and the P-type extension electrode and at an end close to light emitting layer, the current block reflecting layer is disposed.

4. The current block layer structure of an LED of claim 3, wherein the P-type contact is a circular shape, the P-type extension electrode is a long strip.

5. The current block layer structure of an LED of claim 1, wherein another current block reflecting layer is disposed at one side of the N-type electrode close to the reflecting layer.

6. The current block layer structure of an LED of claim 5, wherein the another current block reflecting layer has a pattern that corresponds to the N-type electrode and is in a discontinuous form.

7. The current block layer structure of an LED of claim 6, wherein the N-type electrode comprises divided areas of an N-type contact and an N-type extension electrode that are connected to each other; the another current block reflecting layer is disposed at ends of the N-type contact and the N-type extension electrode close to the reflecting layer, the another current block reflecting layer corresponding to a region of the N-type extension electrode being in a discontinuous form.

8. The current block layer structure of an LED of claim 7, wherein the N-type contact is a circular shape, the N-type extension electrode is a long strip.
